(19) United States
(12) Patent Application Publication
(10) Pub. No.: US 2019/0058011 A1
(43) Pub. Date: Feb. 21, 2019

(54) PHOTOSENSITIVE LAMINATE, METHOD OF MANUFACTURE AND IMAGE SENSOR DEVICES

(71) Applicant: SABIC GLOBAL TECHNOLOGIES B.V., Bergen op Zoom (NL)

(72) Inventor: Anirban Basu, Selkirk, NY (US)

(21) Appl. No.: 16/077,323

(22) PCT Filed: Feb. 8, 2017
(86) PCT No.: PCT/US2017/016944

§ 371 Date: Aug. 10, 2018

Related U.S. Application Data
(60) Provisional application No. 62/294,545, filed on Feb. 12, 2016.
(60) Provisional application No. 62/323,012, filed on Apr. 15, 2016.

(51) Int. Cl. H01L 27/30; H01L 51/44; H01L 51/00

(52) U.S. Cl. CPC H01L 27/307; H01L 51/0035; H01L 51/004; H01L 51/448

(57) ABSTRACT

A photosensitive laminate (121) includes an optically clear polymer film (123) comprising a thermoplastic polymer, and further having a first surface (124) and a second surface (125) opposite the first surface. An organic image sensor layer (126) disposed on at least a portion of the first surface (124) of the optically clear polymer film. A glass layer (122) is laminated directly onto the organic image sensor layer (126) and the first surface (124) of the optically clear polymer film, wherein no adhesive is disposed between the first surface of the optically clear polymer film (124) and the glass layer (122). A method of manufacturing the photosensitive laminate and image sensor devices are also described.

### BACKGROUND

Electronic devices, including mobile electronic devices, personal electronic devices, handheld electronic devices, and the like, often include an organic photoelectric conversion layer-based image sensor, for example in digital cameras, industrial, media and medical image sensing. Existing methods for preparing these sensors include stacking multiple layers using adhesives, together with multiple process steps that require thermal treatment of the intermediate or final stacks. In most cases, the sensor is attached to a coverglass in a separate step using an optically clear adhesive, which adds additional processing complexity and reduces functional efficiency.

Accordingly, there remains a continuing need in the art for improved organic photoelectric conversion layer-based image sensors, as well as methods of making the sensors.

### BRIEF DESCRIPTION

A photosensitive laminate (121) comprises an optically clear polymer film (123) comprising a thermoplastic polymer, and further comprising a first surface (124) and a second surface (125) opposite the first surface; an organic image sensor layer (126) disposed on at least a portion of the first surface (124) of the optically clear polymer film; and a glass layer (122) laminated directly onto the organic image sensor layer (126) and the first surface (124) of the optically clear polymer film, wherein no adhesive is disposed between the first surface of the optically clear polymer film (124) and the glass layer (122).

A method of manufacturing a photosensitive laminate (121) comprises providing the optically clear polymer film (123) comprising the an organic image sensor layer (126) on at least a portion of the first surface (124) of the optically clear polymeric film; and directly laminating the glass layer (122) onto the organic image sensor layer (126) and the first surface (124) of the optically clear polymeric film, wherein no adhesive is disposed between the surface of the optically clear polymer film and the glass layer.

An image sensor device comprises the photosensitive laminate.

The above described and other features are exemplified by the following figures and detailed description.

### BRIEF DESCRIPTION OF THE DRAWINGS

The following figures are exemplary embodiments wherein the like elements are numbered alike.

FIG. 1 shows a cross sectional view of an image sensor device of the prior art.

FIG. 2 shows a cross sectional view of an embodiment of an image sensor device in accordance with an embodiment of the present disclosure.

FIG. 3 shows a cross sectional view of another embodiment of an image sensor device of the present disclosure.

### DETAILED DESCRIPTION

The present inventors have discovered that a photosensitive laminate can be produced by disposing an organic image sensor onto an optically clear polymer film, and then disposing a glass layer on the image sensor and the polymer film to provide a laminate. In contrast to prior organic image sensor-coverglass stacks, the photosensitive laminate can be prepared without the use of an optically clear adhesive between the sensor and the glass layer, and without additional processing steps involving thermal curing. In an advantageous feature, the laminate can be manufactured by roll to roll processing, and cut into the desired shape. This method advantageously allows the manufacture of assemblies for curved or other flexible applications.

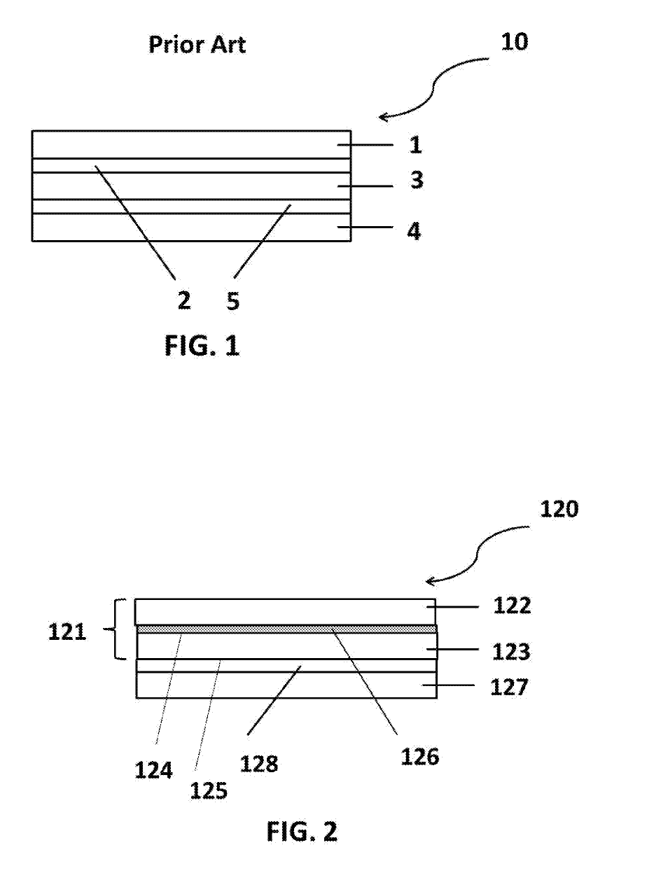

An exemplary prior art organic photoelectric conversion layer-based image sensor is shown in FIG. 1. The organic photoelectric conversion layer-based image sensor (10) includes a coverglass layer (1) disposed on a first optically clear adhesive layer (2), which is disposed on a first surface of a photosensitive layer (3). The photosensitive layer includes a polymer film and an organic image sensor. A second surface of the photosensitive layer (3), which is opposite the first surface of the photosensitive layer, is attached to a sensor unit (e.g., a backend electronics/display interface) (4) via a second optically clear adhesive layer (5).

An aspect of the present disclosure is an image sensor device comprising a photosensitive laminate. As shown in FIG. 2, an embodiment of an image sensor device (120) comprises a photosensitive laminate (121) comprising an optically clear polymer film (123) having a first surface (124) opposite a second surface (125). An organic image sensor layer (126) is disposed on at least a portion of the first surface (124) of the optically clear polymer film (123). The first surface (124) of the optically clear polymer film (123) and the organic image sensor layer (126) are laminated directly to a surface of a glass layer (122). That is, no adhesive is disposed between the first surface of the optically clear polymer film (124) and the glass layer (122). Optionally, the photosensitive laminate (121) can then be attached to a sensor unit (127) with an optically clear adhesive layer (128) disposed on at least a portion of the second side (125) of the optically clear polymer film (123).

The photosensitive laminate comprises an optically clear polymer film. As used herein, the term “optically clear polymer film” means that a 100 micrometer-thick sample of the optically clear polymer film transmits greater than 85% of visible light as determined according to ASTM D1003-00. In some embodiments, the optically clear polymer film can have a thickness of 1 micrometer to 100 micrometers.

The optically clear polymer film comprises a thermoplastic polymer. As used herein, the term “thermoplastic” refers to a material that is plastic or deformable, melts to a liquid when heated, and freezes to a brittle, glassy state when cooled sufficiently. Thermoplastics are typically high molecular weight polymers. Examples of thermoplastic polymers that can be used include polyacetals (e.g., polyoxyethylene and polyoxymethylene), poly(C₁₋₆ alkyl)acrylates, polyacrylamides, polyamides, (e.g., aliphatic polyamides, polyphthalamides, and polyaramides), polyamideimides, polyanhydrides, polyarylates, polyarylene ethers (e.g., polyphenylene ethers), polyarylene sulfides (e.g., polyphenylene sulfides), polyarylsulfones, polybenzothiazoles, polybenzoxazoles, polybenzimidazoles, polycarbonates (including polycarbonate copolymers such as polycarbonate-siloxanes, polycarbonate-esters, and polycarbonate-ester-siloxanes), polyesters (e.g., polyethylene terephthalates, polybutylene terephthalates, polyarylates, and polyester copolymers such as polyester-ethers), polyetheretherketones, polyetherimides (including copolymers such as polyetherimide-siloxane copolymers), polyetherketoneketones, polyetherketones, polyethersulfones, polyimides (including copolymers such as polyimide-siloxane copolymers), poly(C₁₋₆ alkyl)methacrylates, polymethacrylamides, polynorbornenes (including copolymers containing norbornenyl units) polyolefins (e.g., polyethylenes, polypropylenes, polytetrafluoroethylenes, and their copolymers, for example ethylene-alpha-olefin copolymers), polyoxadiazoles, polyoxymethylene, polyphthalides, polysilazanes, polysiloxanes, polystyrenes (including copolymers such as acrylonitrile-butadiene-styrene (ABS) and methyl methacrylate-butadiene-styrene (MBS)), polysulfides, polysulfonamides, polysulfonates, polysulfones, polythioesters, polytriazines, polyureas, polyurethanes, polyvinyl alcohols, polyvinyl esters, polyvinyl ethers, polyvinyl halides, polyvinyl nitriles, polyvinyl ketones, polyvinyl thioethers, polyvinylidene fluorides, or the like, or a combination comprising at least one of the foregoing thermoplastic polymers.

In some embodiments, the polymer film comprises a polyacetal, poly(C₁₋₆ alkyl)acrylate, polyarylate, polycarbonate, polyester, polyetherimide, polyimide, poly(C₁₋₆ alkyl)methacrylate, polyolefin, polystyrene, polyurethane, polyvinyl alcohol, polyvinyl ester, polyvinyl ether, polyvinyl halide, polyvinyl nitrile, polyvinyl ketone, polyvinylidene fluoride, or a combination comprising at least one of the foregoing thermoplastic polymers. In some embodiments, the polymer film comprises a polyimide, a polyetherimide, a polyester, a polyolefin, a polycarbonate, a (meth)acrylic polymer (e.g., poly(C₁₋₆ alkyl)acrylates, poly(C₁₋₆ alkyl)methacrylates, or a combination comprising at least one of the foregoing, preferably poly(methyl methacrylate)), a vinyl polymer, polyacetal (e.g., polyoxyethylene and polyoxymethylene), a styrenic polymer, or a combination comprising at least one of the foregoing. In some embodiments, the optically clear polymer film comprises a polyimide, a polyetherimide, a polyester, a polyolefin, a polycarbonate, or a combination comprising at least one of the foregoing. In some embodiments, the optically clear polymer film comprises poly(methyl methacrylate), a polycarbonate, or a combination comprising at least one of the foregoing.

In some embodiments, the optically clear polymer film can include a polycarbonate. Polycarbonates and their methods of manufacture are known in the art, being described, for example, in WO 2013/175448 A1, US 2014/0295363, and WO 2014/072923. In a specific embodiment, the polycarbonate is a linear homopolymer containing bisphenol A carbonate units (BPA-PC), commercially available under the trade name LEXAN from SABIC; or a branched, cyanophenol end-capped bisphenol A homopolycarbonate produced via interfacial polymerization, containing 3 mol % 1,1,1-tris(4-hydroxyphenyl)ethane (THPE) branching agent, commercially available under the trade name LEXAN CFR from SABIC. A combination of a linear polycarbonate and a branched polycarbonate can be used. It is also possible to use a polycarbonate copolymer or interpolymer rather than a homopolymer. Polycarbonate copolymers can include copolycarbonates comprising two or more different types of carbonate units, for example units derived from BPA and PPPBP (commercially available under the trade name XHT from SABIC); BPA and DMBPC (commercially available under the trade name DMX from SABIC); or BPA and isophorone bisphenol (commercially available under the trade name APEC from Bayer). The polycarbonate copolymers can further comprise non-carbonate repeating units, for example repeating ester units (polyester-carbonates), such as those comprising resorcinol isophthalate and terephthalate units and bisphenol A carbonate units, such as those commercially available under the trade name LEXAN SLX from SABIC; bisphenol A carbonate units and isophthalate-terephthalate-bisphenol A ester units, also commonly referred to as poly(carbonate-ester)s (PCE) or poly(phthalate-carbonate)s (PPC), depending on the relative ratio of carbonate units and ester units; or bisphenol A carbonate units and C₆₋₁₂ dicarboxy ester units such as sebacic ester units (commercially available under the trade name HFD from SABIC) Other polycarbonate copolymers can comprise repeating siloxane units (polycarbonate-siloxanes), for example those comprising bisphenol A carbonate units and siloxane units (e.g., blocks containing 5 to 200 dimethylsiloxane units), such as those commercially available under the trade name EXL from SABIC; or both ester units and siloxane units (polycarbonate-ester-siloxanes), for example those comprising bisphenol A carbonate units, isophthalate-terephthalate-bisphenol A ester units, and siloxane units (e.g., blocks containing 5 to 200 dimethylsiloxane units), such as those commercially available under the trade name FST from SABIC. Combinations of any of the above materials can be used.

Combinations of polycarbonates with other polymers can be used, for example an alloy of bisphenol A polycarbonate with an ester such as poly(butylene terephthalate) or poly(ethylene terephthalate), each of which can be semicrystalline or amorphous. Such combinations are commercially available under the trade name XENOY and XYLEX from SABIC.

A specific copolycarbonate includes bisphenol A and bulky bisphenol carbonate units, i.e., derived from bisphenols containing at least 12 carbon atoms, for example 12 to 60 carbon atoms or 20 to 40 carbon atoms. Examples of such copolycarbonates include copolycarbonates comprising bisphenol A carbonate units and 2-phenyl-3,3′-bis(4-hydroxyphenyl) phthalimidine carbonate units (a BPA-PPPBP copolymer, commercially available under the trade designation LEXAN XHT from SABIC), a copolymer comprising bisphenol A carbonate units and 1,1-bis(4-hydroxy-3-methylphenyl)cyclohexane carbonate units (a BPA-DMBPC copolymer commercially available under the trade designation LEXAN DMC from SABIC, or a copolymer comprising bisphenol A carbonate units and isophorone bisphenol carbonate units (commercially available under the trade name APEC from Bayer). A combination of linear polycarbonate and a branched polycarbonate can be used. Moreover, combinations of any of the above materials may be used.

The polycarbonates can have an intrinsic viscosity, as determined in chloroform at 25° C., of 0.3 to 1.5 deciliters per gram (dl/gm), specifically 0.45 to 1.0 dl/gm. The polycarbonates can have a weight average molecular weight of 10,000 to 200,000 Daltons, specifically 20,000 to 100,000 Daltons, as measured by gel permeation chromatography (GPC), using a crosslinked styrene-divinylbenzene column and calibrated to polycarbonate references. GPC samples are prepared at a concentration of 1 mg per ml, and are eluted at a flow rate of 1.5 ml per minute.

In some embodiments, the optically clear polymer film can include a polyester (e.g., polyethylene terephthalates, polybutylene terephthalates, polyarylates, and polyester copolymers such as polyester-ethers). In some embodiments, the polyester can include a poly(ethylene terephthalate), a glycol-modified poly(ethylene terephthalate), a poly(ethylene naphthalate), poly(1,4-cyclohexane-dimethanol-1,4-cyclohexane dicarboxylate), poly(cyclohexanedimethylene terephthalate)-co-poly(ethylene terephthalate), or a combination comprising at least one of the foregoing polyesters.

In some embodiments, the optically clear polymer film can include a polyolefin. Representative examples of polyolefins as thermoplastic polymers are polyethylene, polypropylene, polybutylene, polymethylpentene (and co-polymers thereof), polynorbornene (and co-polymers thereof), poly(1-butene), poly(3-methylbutene), poly(4-methylpentene) and copolymers of ethylene with propylene, 1-butene, 1-hexene, 1-octene, 1-decene, 4-methyl-1-pentene and 1-octadecene. Representative combinations of polyolefins are combinations containing polyethylene and polypropylene, low-density polyethylene and high-density polyethylene, and polyethylene and olefin copolymers containing copolymerizable monomers, some of which are described above, e.g., ethylene and acrylic acid copolymers; ethyl and methyl acrylate copolymers; ethylene and ethyl acrylate copolymers; ethylene and vinyl acetate copolymers, ethylene, acrylic acid, and ethyl acrylate copolymers, and ethylene, acrylic acid, and vinyl acetate copolymers. In some embodiments, the thermoplastic polymer can include a polyolefin elastomer.

In some embodiments, the optically clear polymer film can include a vinyl polymer, for example, polyvinyl alcohols, polyvinyl esters, polyvinyl ethers, polyvinyl halides (e.g., polyvinyl fluoride), polyvinyl nitriles, polyvinyl ketones, polyvinyl thioethers, or a combination comprising at least one of the foregoing. In some embodiments, the optically clear polymer film can include a styrenic polymer, for example polystyrene and copolymers thereof including acrylonitrile-butadiene-styrene (ABS) and methyl methacrylate-butadiene-styrene (MBS).

In some embodiments, one or both surfaces of the polymer film can be a textured surface, which can provide, for example, anti-glare properties, anti-reflective properties, anti-microbial properties, and the like, or a combination comprising at least one of the foregoing.

The polymer film can be prepared using any method for preparing a polymer film that is generally known. For example, the polymer film can be prepared by extrusion, solution casting, melt blowing, and the like.

In some embodiments, the optically clear polymer film is a multilayer polymer film comprising two or more optically clear polymer layers which can be disposed on, adhered via and adhesive, or otherwise joined, for example laminated, to provide the multilayer film. Each layer of the optically clear polymer film can comprise the same or a different polymer.

As shown in FIG. 2, one or more organic image sensor layers are disposed on at least a portion of the first surface of the optically clear polymer film. In one aspect, the organic image sensor is an organic CMOS image sensor, comprising for example an organic photoelectric conversion layer arranged between an anode and a cathode. Thus, a CMOS image sensor can comprise an anode, a photoelectric conversion layer disposed over the anode, and a cathode disposed over a surface of the photoelectric conversion layer opposite the anode.

The organic photoelectric conversion layer may be a single layer film, or may be a multilayer film. In an aspect, an organic photoelectric conversion layer comprises an organic semiconductor. Exemplary organic semiconductors include phthalocyanine material and a naphthalocyanine material such as fullerene, coumarin 6 (C6), rhodamine 6G (R6G), quinacridon, and zinc phthalocyanine (ZnPc). The organic photoelectric conversion layer may be formed by a composite material using both an inorganic material and an organic material. Inorganic semiconductors include Si and Ge, GaAs and ZnO, BN, GaP, AlSb, GaAlAsP, CdSe, ZnS, and HdTe, PbS, PbTe, CuO, and the like.

In certain aspects, the organic image sensor comprises a plurality of individual optical sensors, referred to as pixels. Each pixel can include multiple layers that are stacked on top of each one another, and are formed by photolithography or spin on coating techniques.

In some aspects, an electrode, the anode, the cathode, or both, comprises a pixel electrode array. Pixel electrodes, for example, can comprise single layer or multilayer films. Exemplary materials for the electrodes include conductive metal oxides, such as tin oxides doped with antimony or fluorine (ATO, FTO), tin oxides, zinc oxides, indium oxides, indium tin oxide (ITO), indium zinc oxides (IZO), GZO (gallium-doped zinc oxide), and the like; metals, such as gold, silver, chrome, nickel, titanium, tungsten, aluminum, and the like; conductive compounds, such as oxides and nitrides of these metals (titanium nitride (TiN) by way of example); mixtures or layered body of these metals and conductive metal oxides; inorganic conductive substances, such as copper iodide, copper sulfide, and the like; organic conductive materials, such as polyaniline, polythiophene and polypyrrole; and layered bodies of these and ITO or titanium nitride.

As shown in FIG. 2, a glass layer is then disposed on the surface of the optically clear polymer film that comprises the organic image sensor. The glass layer has a first surface and a second surface opposite the first surface. The glass layer can be, but is not limited to, chemically strengthened glass (e.g., CORNING™ GORILLA™ Glass commercially available from Corning Inc., XENSATION™ glass commercially available from Schott AG, DRAGONTRAIL™ glass commercially available from Asahi Glass Company, LTD, and CX-01 glass commercially available from Nippon Electric Glass Company, LTD, and the like), non-strengthened glass such as non-hardened glass including low sodium glass (e.g., CORNING™ WILLOW™ Glass commercially available from Corning Inc. and OA-10G Glass-on-Roll glass commercially available from Nippon Electric Glass Company, LTD, and the like), tempered glass, or optically transparent synthetic crystal (also referred to as sapphire glass, commercially available from GT Advanced Technologies Inc.).

The glass layer can have a thickness of 50 micrometers to 1 millimeter.

In some embodiments, one or both surfaces of the glass layer can be a textured surface, which can provide, for example, anti-glare properties, anti-reflective properties, anti-microbial properties, and the like, or a combination comprising at least one of the foregoing.

Exemplary properties for the photosensitive laminate are a thickness of less than 1 millimeter , a transmission of greater than 80%, preferably greater than 90% of visible light as determined according to ASTM D1003-00, a haze of less than 1%, preferably less than 5%, as determined according to ASTM D1003-00, a flex modulus of greater than 5 measured according to JIS K6902, a pencil hardness of greater than 5H, or greater than 7H, or greater than 9H measured according to ASTM 3363, and a scratch resistance of less than 5% according to ASTM D7027.

Optionally, an optically clear coating is present on at least a portion of the surface of the glass layer opposite the optically clear polymer film. The method can further comprise disposing the optically clear coating to the desired portion of the second surface of the glass layer. The disposing can be by, for example, roll lamination, roller coating, screen printing, spreading, spray coating, spin coating, dip coating, and the like, or a combination comprising at least one of the foregoing techniques. In some embodiments, a film of the optically clear coating can be prepared and subsequently laminated to the desired portion of the cover assembly.

In certain embodiments, the photosensitive laminate is in the form of a roll. The roll can comprise, for example multiple sensor coverglasses which can be cut from the roll.

A method of manufacturing a photosensitive laminate comprises providing an optically clear polymer film having a first surface and a second surface; disposing one or more organic image sensor layers onto the second surface of the optically clear polymeric film; and directly laminating a glass layer onto the second surface of the optically clear polymeric film comprising the one or more organic image sensor layers, wherein no adhesive is disposed between the second surface of the optically clear polymer film and the glass layer.

In some embodiments, when the optically transparent polymer film comprises a multilayer film, the multilayer film manufactured by laminating two or more optically clear polymer layers, wherein each optically clear polymer layer comprises the same or a different thermoplastic polymer. Roll lamination, such as in a roll-to roll (R2R) process can be used to laminate the polymer film layers. Optionally, two or more layers of the multilayer film comprise one or more organic image sensor layers.

Disposing one or more organic image sensor layers onto the second surface of the optically clear polymeric film can be performed by printing and/or coating.

Disposing a glass layer onto the second surface of the optically transparent polymer film can comprise a roll lamination or roller coating process, such as an R2R process.

Also disclosed herein is an image sensor device comprising the photosensitive laminate. An optically clear adhesive layer is disposed between the first surface of the optically clear polymer film, opposite the glass surface, and a sensor unit such as a display unit/backend electronics.

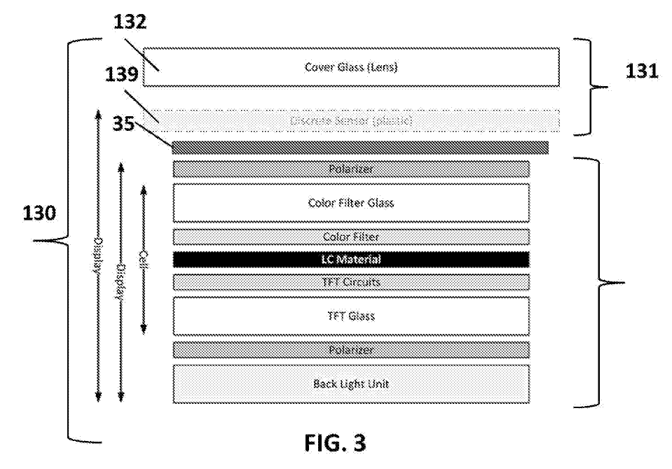

An image sensor device is shown in FIG. 3. The sensor device (130) comprises a photosensitive laminate (131) comprising a glass layer (132) having a surface laminated directly to a first surface of a photosensitive layer (139) which comprises one or more organic image sensor layers and one or more optically clear polymer layers as described herein. The laminate (131) is attached to a sensor unit (140) with an optically clear adhesive layer (138).

An optically clear adhesive is defined as an adhesive wherein a 50 micrometer-thick sample of the optically clear adhesive transmits greater than 85% of visible light as determined according to ASTM D1003-00. In some embodiments, the optically clear adhesive layer is in adhesive contact with the entire first surface of the glass layer. When present, the optically clear adhesive layer can have a thickness of 25 to 500 micrometers.

The adhesive can include epoxy, acrylate, amine, urethane, silicone, thermoplastic urethane, ethyl vinyl acetate, hindered amine light stabilizer free ethyl vinyl acetate (HALS free EVA), or a combination comprising at least one of the foregoing. In an embodiment, the adhesive is a hindered amine light stabilizer free ethyl vinyl acetate (HALS free EVA). In an embodiment the adhesive is a thermoplastic urethane, or an ultra violet light cured modified acrylate optical quality adhesive, or a silicone pressure sensitive adhesive, or an acrylate pressure sensitive adhesive. The adhesive can be applied using a process such as roll lamination, roller coating, screen printing, spreading, spray coating, spin coating, dip coating, and the like, or a combination comprising at least one of the foregoing techniques.

Disposing an optically clear adhesive layer onto the first surface of the optically clear polymer film is performed using, for example, roll lamination such as an R2R process, roller coating, screen printing, spreading, spray coating, spin coating, dip coating, and the like, or a combination comprising at least one of the foregoing techniques.

The sensor unit can include a variety of components such as polarizers, color glass filters, glass filters, liquid crystal materials, thin film transistor (TFT) circuits, TFT glass, and back light units, as would be found in display units, for example.

In addition, a microlens array can be disposed on a surface of the glass layer opposite the photosensitive layer.

Examples of electronic devices that can be utilized with the image sensor device include but are not limited to, a cellular telephone, a smart telephone, a laptop computer, a notebook computer, a tablet computer, a smart window, public information displays, or a wearable electronic device (e.g., smart watch, activity tracker, health tracker, health monitoring devices, and the like). In some embodiments, the photosensitive laminate can further serve as a barrier layer for oxygen and moisture, such that no additional barrier layer is required (i.e., to protect the electronic device from oxygen and moisture). The image sensor devices are particularly useful in touch screen applications.

This disclosure further encompasses the following non-limiting embodiments.

Embodiment 1: A photosensitive laminate (121) comprising an optically clear polymer film (123) comprising a thermoplastic polymer, and further comprising a first surface (124) and a second surface (125) opposite the first surface; an organic image sensor layer (126) disposed on at least a portion of the first surface (124) of the optically clear polymer film; and a glass layer (122) laminated directly onto the organic image sensor layer (126) and the first surface (124) of the optically clear polymer film, wherein no adhesive is disposed between the first surface of the optically clear polymer film (124) and the glass layer (122).

Embodiment 2: The photosensitive laminate of embodiment 1, wherein the organic image sensor layer comprises an organic CMOS image sensor.

Embodiment 3: The photosensitive laminate of embodiment 2, wherein the organic CMOS image sensor comprises an anode, a photoelectric conversion layer disposed over the anode, and a cathode disposed over a surface of the photoelectric conversion layer opposite the anode.

Embodiment 4: The photosensitive laminate of embodiment 3, wherein the photoelectric conversion layer comprises an organic semiconductor.

Embodiment 5: The photosensitive laminate of embodiment 3, wherein the anode, the cathode, or both, comprises a pixel electrode array.

Embodiment 6: The photosensitive laminate of any one or more of embodiments 1 to 5, wherein a 100 micrometer-thick sample of the optically clear polymer film transmits greater than 85% of visible light as determined according to ASTM D1003-00.

Embodiment 7: The photosensitive laminate of any one or more of embodiments 1 to 6, wherein the glass layer comprises chemically strengthened glass, non-strengthened glass, tempered glass, or optically transparent synthetic crystal.

Embodiment 8: The photosensitive laminate of embodiment 7, wherein the glass layer has a thickness of 50 micrometers to 1 millimeter, preferably 50 micrometers to 0.7 millimeter, more preferably 50 to 400 micrometers.

Embodiment 9: The photosensitive laminate of embodiment 1, wherein the optically clear polymer film comprises a polyacetal, poly(C₁₋₆ alkyl)acrylate, polyarylate, polycarbonate, polyester, polyetherimide, polyimide, poly(C₁₋₆ alkyl)methacrylate, polyolefin, polystyrene, polyurethane, polyvinyl alcohol, polyvinyl ester, polyvinyl ether, polyvinyl halide, polyvinyl nitrile, polyvinyl ketone, polyvinylidene fluoride, or a combination comprising at least one of the foregoing thermoplastic polymers, preferably wherein the polymer film comprises poly(ethylene terephthalate), poly(ethylene naphthalate), poly(1,4-cyclohexane-dimethanol-1,4-cyclohexane dicarboxylate), poly(cyclohexanedimethylene terephthalate)-co-poly(ethylene terephthalate), polyethylene, polypropylene, a bisphenol A polycarbonate homopolymer, a bisphenol A polycarbonate copolymer, poly(4,4′-oxydiphenylene-pyromellitimide), polyvinylidene fluoride, polyvinyl fluoride, poly(methyl methacrylate), polystyrene, polyoxymethylene, ethyl vinyl acetate, polymethylpentane, or a combination comprising at least one of the foregoing.

Embodiment 10: The photosensitive laminate of embodiment 9, wherein the optically clear polymer film has a thickness of 1 micrometer to 20 millimeters, preferably 5 micrometers to 20 millimeters, more preferably 5 micrometers to 10 millimeters, even more preferably 5 micrometers to 1 millimeter, even more preferably still 5 to 250 micrometers, most preferably 5 to 100 micrometers.

Embodiment 11: A method of manufacturing the photosensitive laminate (121) of any one or more of embodiments 1 to 10, the method comprising providing the optically clear polymer film (123) comprising the an organic image sensor layer (126) on at least a portion of the first surface (124) of the optically clear polymeric film; and directly laminating the glass layer (122) onto the organic image sensor layer (126) and the first surface (124) of the optically clear polymeric film, wherein no adhesive is disposed between the surface of the optically clear polymer film and the glass layer.

Embodiment 12: The method of embodiment 11, wherein the photosensitive laminate is manufactured by a roll to roll lamination process.

Embodiment 13: The method of embodiment 12, further comprising disposing an optically clear adhesive layer (126) on at least a portion of the second side (125) of the optically clear polymer film (123) and disposing a sensor unit (126) on a side of the optically clear adhesive layer opposite the optically clear polymer film to provide a sensor device.

Embodiment 14: An image sensor device comprising the photosensitive laminate (121) of any one of embodiments 1-10.

Embodiment 15: The image sensor device of embodiment 14, wherein the photosensitive laminate (121) is disposed on a sensor unit (126).

Embodiment 16: The image sensor device of embodiment 14, wherein the photosensitive laminate is disposed on a sensor unit using an optically clear adhesive layer, wherein a 50 micrometer-thick sample of the optically clear adhesive transmits greater than 85% of visible light as determined according to ASTM D1003-00.

Embodiment 17: The image sensor device of any one or more of embodiments 14 to 16, wherein the device is a cellular telephone, a smart telephone, a laptop computer, a notebook computer, or a tablet computer.

Embodiment 18: The image sensor device of embodiment 17, wherein the device comprises a touch screen display comprising the photosensitive laminate.

The assemblies, methods, and devices can alternatively comprise, consist of, or consist essentially of, any appropriate components or steps herein disclosed. The assemblies, methods, and devices can additionally, or alternatively, be formulated so as to be devoid, or substantially free, of any steps, components, materials, ingredients, adjuvants, or species that are otherwise not necessary to the achievement of the function or objectives of the assemblies, methods, and devices.

All ranges disclosed herein are inclusive of the endpoints, and the endpoints are independently combinable with each other. “Combinations” is inclusive of blends, mixtures, alloys, reaction products, and the like. The terms “first,” “second,” and the like, do not denote any order, quantity, or importance, but rather are used to distinguish one element from another. The terms “a” and “an” and “the” do not denote a limitation of quantity, and are to be construed to cover both the singular and the plural, unless otherwise indicated herein or clearly contradicted by context. “Or” means “and/or” unless clearly stated otherwise. Reference throughout the specification to “some embodiments,” “an embodiment,” and so forth, means that a particular element described in connection with the embodiment is included in at least some embodiments described herein, and may or may not be present in other embodiments. In addition, it is to be understood that the described elements may be combined in any suitable manner in the various embodiments.

Unless defined otherwise, technical and scientific terms used herein have the same meaning as is commonly understood by one of skill in the art to which this application belongs. All cited patents, patent applications, and other references are incorporated herein by reference in their entirety. However, if a term in the present application contradicts or conflicts with a term in the incorporated reference, the term from the present application takes precedence over the conflicting term from the incorporated reference.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

1. A photosensitive laminate (121), comprising
an optically clear polymer film (123) comprising a thermoplastic polymer, and further comprising a first surface (124) and a second surface (125) opposite the first surface;
an organic image sensor layer (126) disposed on at least a portion of the first surface (124) of the optically clear polymer film; and
a glass layer (122) laminated directly onto the organic image sensor layer (126) and the first surface (124) of the optically clear polymer film, wherein no adhesive is disposed between the first surface of the optically clear polymer film (124) and the glass layer (122).

2. The photosensitive laminate of claim 1, wherein the organic image sensor layer comprises an organic CMOS image sensor.

3. The photosensitive laminate of claim 2, wherein the organic CMOS image sensor comprises an anode, a photoelectric conversion layer disposed over the anode, and a cathode disposed over a surface of the photoelectric conversion layer opposite the anode.

4. The photosensitive laminate of claim 3, wherein the photoelectric conversion layer comprises an organic semiconductor.

5. The photosensitive laminate of claim 3, wherein the anode, the cathode, or both, comprises a pixel electrode array.

6. The photosensitive laminate of claim 1, wherein
a 100 micrometer-thick sample of the optically clear polymer film transmits greater than 85% of visible light as determined according to ASTM D1003-00.

7. The photosensitive laminate of claim 1, wherein the glass layer comprises chemically strengthened glass, non-strengthened glass, tempered glass, or optically transparent synthetic crystal.

8. The photosensitive laminate of claim 7, wherein the glass layer has a thickness of 50 micrometers to 1 millimeter.

9. The photosensitive laminate of claim 1, wherein the optically clear polymer film comprises a polyacetal, poly(C₁₋₆ alkyl)acrylate, polyarylate, polycarbonate, polyester, polyetherimide, polyimide, poly(C₁₋₆ alkyl)methacrylate, polyolefin, polystyrene, polyurethane, polyvinyl alcohol, polyvinyl ester, polyvinyl ether, polyvinyl halide, polyvinyl nitrile, polyvinyl ketone, polyvinylidene fluoride, or a combination comprising at least one of the foregoing thermoplastic polymers.

10. The photosensitive laminate of claim 9, wherein the optically clear polymer film has a thickness of 1 micrometer to 100 micrometers.

11. A method of manufacturing the photosensitive laminate (121) of claim 1, the method comprising
providing the optically clear polymer film (123) comprising the an organic image sensor layer (126) on at least a portion of the first surface (124) of the optically clear polymeric film; and
directly laminating the glass layer (122) onto the organic image sensor layer (126) and the first surface (124) of the optically clear polymeric film, wherein no adhesive is disposed between the surface of the optically clear polymer film and the glass layer.

12. The method of claim 11, wherein the photosensitive laminate is manufactured by a roll to roll lamination process.

13. The method of claim 12, further comprising disposing an optically clear adhesive layer (126) on at least a portion of the second side (125) of the optically clear polymer film (123) and disposing a sensor unit (126) on a side of the optically clear adhesive layer opposite the optically clear polymer film to provide a sensor device.

14. An image sensor device comprising the photosensitive laminate (121) of claims 1.

15. The image sensor device of claim 14, wherein the photosensitive laminate (121) is disposed on a sensor unit (126).

16. The image sensor device of claim 14, wherein the photosensitive laminate is disposed on a sensor unit using an optically clear adhesive layer, wherein a 50 micrometer-thick sample of the optically clear adhesive transmits greater than 85% of visible light as determined according to ASTM D1003-00.

17. The image sensor device of claim 1, wherein the device is a cellular telephone, a smart telephone, a laptop computer, a notebook computer, or a tablet computer.

18. The image sensor device of claim 17, wherein the device comprises a touch screen display comprising the photosensitive laminate.
